(19) United States
(12) Patent Application Publication
(10) Pub. No.: US 2013/0222036 A1
(43) Pub. Date: Aug. 29, 2013

(54) VOLTAGE LEVEL CONVERTING CIRCUIT

(71) Applicant: Tae Heui KWON, Icheon-si (KR)

(72) Inventor: Tae Heui KWON, Icheon-si (KR)

(73) Assignee: SK HYNIX INC., Icheon-si (KR)

(21) Appl. No.: 13/600,130

(22) Filed: Aug. 30, 2012

(30) Foreign Application Priority Data
Feb. 23, 2012 (KR) 10-2012-0018281

(51) Int. Cl. H03L 5/00

(52) U.S. Cl. 327/333

(57) ABSTRACT

A voltage level converting circuit includes: a voltage level converting block configured to convert an input signal having a first voltage level into an output signal having a second voltage level; and a boosting block connected to an input stage and an inverting input stage of the voltage level converting block, and configured to provide a negative voltage to the input stage or the inverting input stage.

### CROSS-REFERENCES TO RELATED APPLICATION

The present application claims priority under 35 U.S.C. §119(a) to Korean application number 10-2012-0018281, filed on Feb. 23, 2012, in the Korean Intellectual Property Office, which is incorporated herein by reference in its entirety.

### BACKGROUND

1. Technical Field

The present invention relates generally to an integrated circuit, and more particularly to a voltage level converting circuit.

2. Related Art

With broadening uses of mobile devices, various operation characteristics are required for mobile devices. For example, mobile devices may need to stably operate for a long time even without using a large capacity battery. Therefore, various energy saving methods are being used in mobile devices. For example, two different functional blocks of the mobile device may be supplied with different external voltages. That is, a high voltage is applied to a functional block requiring high performance, but a low voltage is applied to a functional block requiring low performance. Since different voltages are supplied to the respective functional blocks, leakage current may increase at interfaces of the function blocks, or the function blocks may not operate normally.

A voltage level converting circuit (or “level shifter circuit”) may be used at the interfaces of the function blocks. When input and output signals of the voltage level converting circuit have different levels from each other, the voltage level converting circuit may cause signal transition delay or output signal error.

FIG. 1 is a circuit diagram of a known inverter circuit. FIG. 2 is a table showing input/output characteristics of the inverter circuit illustrated in FIG. 1. In general, a transition delay or output signal error occurring during signal transmission is determined by a gate-source voltage of a transistor forming a signal transmission path.

For example, referring to FIGS. 1 and 2, when an input signal inputted to an input terminal IN of the inverter transits from a low level such as a ground voltage to a high level such as a first voltage V1, an NMOS transistor N10 is turned on and an output signal outputted to an output terminal OUT of the inverter transits from a high level such as a power supply voltage Vdd to a low level such as the ground voltage. Similarly, when the input signal inputted to the input terminal IN of the inverter transits from a low level such as the ground voltage to a high level such as a second voltage V2, the NMOS transistor N10 is turned on and the output signal outputted to the output terminal OUT of the inverter transits from a high level such as the power supply voltage Vdd to a low level such as the ground voltage.

The high-low transition delay of the output signal may be determined by a gate-source voltage of the NMOS transistor N10. Furthermore, an error of the output signal may be caused by the gate-source voltage of the NMOS transistor N10 and a current flowing through the NMOS transistor N10. Suppose that the first voltage V1 is higher than the second voltage V2. In this case, the gate-source voltage of the NMOS transistor N10 when the first voltage V1 is applied to the input terminal IN is larger than the gate-source voltage of the NMOS transistor N10 when the second voltage V2 is applied to the input terminal IN. For this reason, an amount of current flowing through the NMOS transistor N10 when the first voltage V1 is applied to the input terminal IN is larger than an amount of current flowing through the NMOS transistor N10 when the second voltage V2 is applied to the input terminal IN. This means that the transition time of the output signal of the inverter when the first voltage V1 is applied to the input terminal IN may be faster than the transition time of the output signal of the inverter when the second voltage V2 is applied to the input terminal IN. Furthermore, the voltage level of the output signal when the first voltage V1 is applied to the input terminal IN may be more stable than the voltage level of the output signal when the second voltage V2 is applied to the input terminal IN.

That is, the transition delay time or the stability of the output signal may be determined according to the voltage level of the input signal applied to the input terminal IN. Therefore, the voltage level converting circuit, of which the input and output signals have different levels from each other, needs to stably operate regardless of the voltage level of the input signal.

### SUMMARY

A voltage level converting circuit capable of stably operating regardless of the voltage level of an input signal is described herein.

In an embodiment of the present invention, a voltage level converting circuit includes: a voltage level converting block configured to convert an input signal having a first voltage level into an output signal having a second voltage level; and a boosting block connected to an input stage and an inverting input stage of the voltage level converting block, and configured to provide a negative voltage to the input stage or the inverting input stage.

The input stage may include a first NMOS transistor, and the inverting input stage may include a second NMOS transistor.

The boosting block may include a first boosting block configured to generate a negative voltage in response to the input signal and provide the generated negative voltage to a source of the first NMOS transistor.

The boosting block may further include a second boosting block configured to generate a negative voltage in response to an inverted input signal obtained by inverting the input signal, and provide the generated negative voltage to a source of the second NMOS transistor.

According to a logic state of the input signal, any one of the first and second boosting blocks may be operated.

In an embodiment of the present invention, a voltage level converting circuit includes: a voltage level converting block configured to convert an input signal having a first voltage level into an output signal having a second voltage level; and a boosting block configured to provide a negative voltage to a first node of the voltage level converting block in response to the input signal, or provide a negative voltage to a second node of the voltage level converting block in response to an inverted input signal obtained by inverting the input signal.

The first node may be connected to a source of a first NMOS transistor forming an input stage of the voltage level converting block, which receives the input signal, and the second node may be connected to a source of a second NMOS transistor forming an inverting input stage of the voltage level converting block, which receives the inverted input signal.

### BRIEF DESCRIPTION OF THE DRAWINGS

Features, aspects, and embodiments are described in conjunction with the attached drawings, in which:

FIG. 1 is a circuit diagram of a known inverter circuit;

FIG. 2 is a table showing input/output characteristics of the inverter circuit illustrated in FIG. 1;

FIG. 3 is a block diagram illustrating a voltage level converting circuit according to an embodiment of the present invention;

FIG. 4 is a circuit diagram illustrating the voltage converting circuit according to an embodiment of the present invention;

FIG. 5 is a diagram explaining the operation of the voltage level converting circuit according to an embodiment of the present invention;

FIG. 6 is another diagram explaining the operation of the voltage level converting circuit according to an embodiment of the present invention; and

FIG. 7 is a circuit diagram illustrating the voltage level converting circuit according to an embodiment of the present invention.

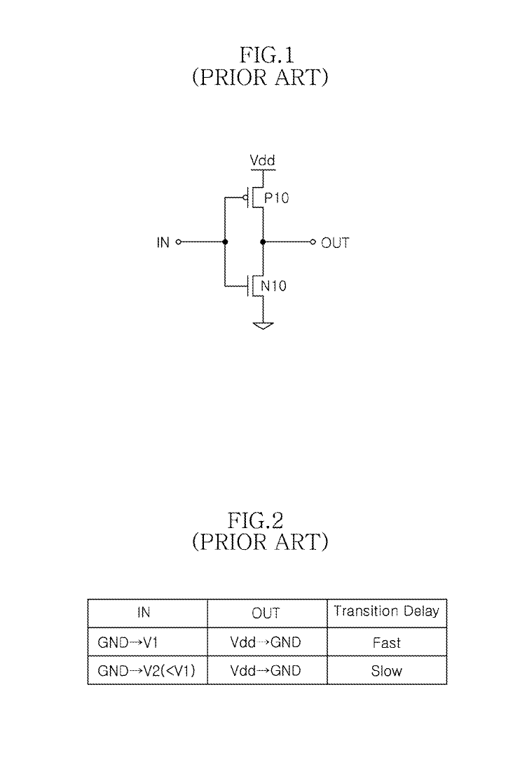

### DETAILED DESCRIPTION

Hereinafter, a voltage level converting circuit according to the present invention will be described below with reference to the accompanying drawings through exemplary embodiments. However, the present invention is not limited to the embodiments to be described herein, but may be embodied into other forms. The embodiments are provided to describe the present invention such that the concept of the present invention may be easily understood by those skilled in the art.

In the drawings, the embodiments of the present invention are not limited to illustrated specific forms, but are exaggerated for clarity. In this specification, specific terms are used to describe the present invention, but do not limit the scope of the present invention.

In this specification, terms such as and/or include any item among combinations of a plurality of related items or the plurality of related items. Furthermore, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The terminology used herein is for the purpose of describing particular embodiments only and is not intended to be limiting of the invention. As used herein, the singular forms are intended to include the plural forms as well, unless the context clearly indicates otherwise. It will be further understood that the terms “comprise”, “comprising”, “have” and/or “having”, when used herein, specify the presence of stated features, integers, steps, operations, elements, and/or components, but do not preclude the presence or addition of one or more other features, integers, steps, operations, elements, components, and/or groups thereof.

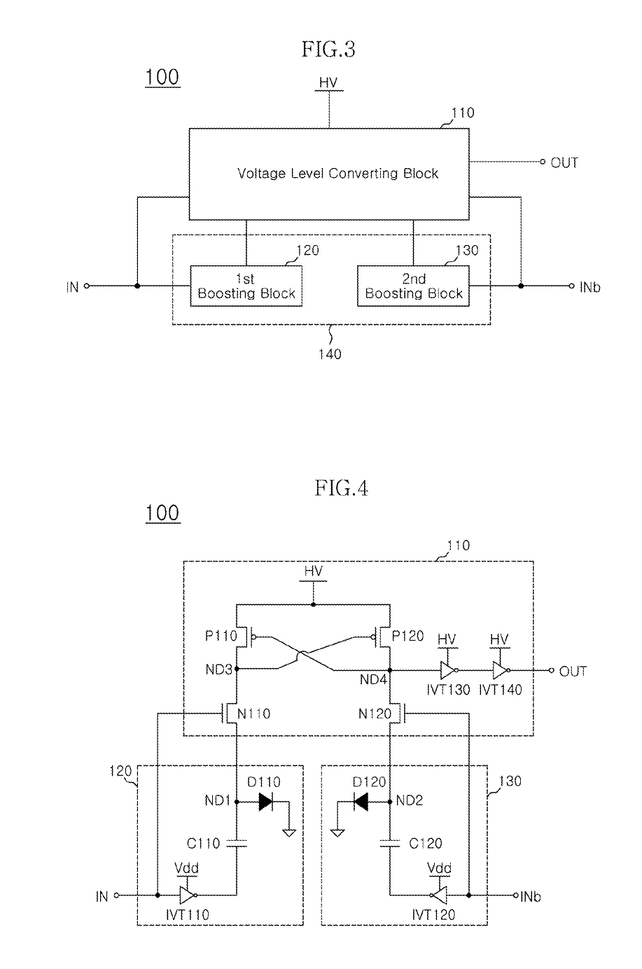

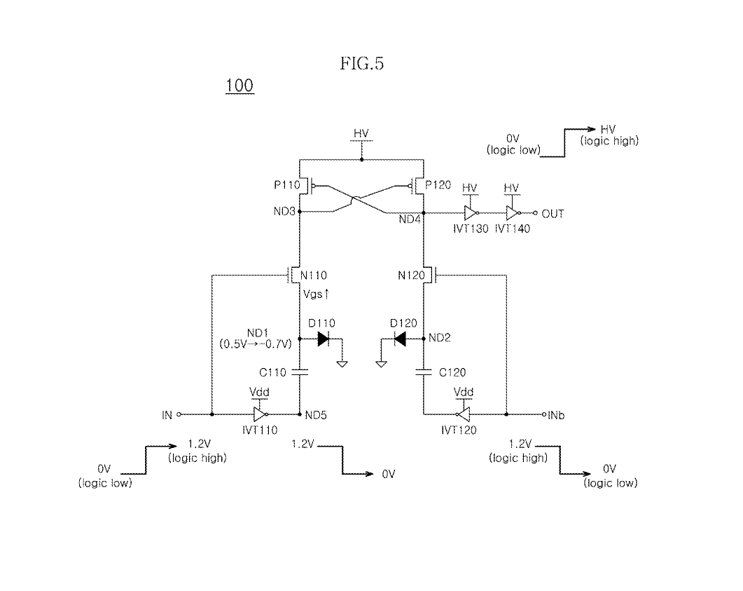

FIG. 3 is a block diagram illustrating a voltage level converting circuit according to an embodiment of the present invention. Referring to FIG. 3, the voltage level converting circuit 100 includes a voltage level converting block 110, for converting a voltage level, and a boosting block 140.

The voltage level converting block 110 is connected between an input terminal IN for receiving an input signal and an output terminal OUT for outputting an output signal. The voltage level converting block 110 is configured to convert the voltage level of the input signal and output the converted signal as the output signal. That is, the input signal inputted to the voltage level converting block 110 and the output signal outputted from the voltage level converting block 110 have different voltage levels from each other.

For example, the voltage level of the input signal inputted to the voltage level converting block 110 may be lower than the voltage level of the output signal outputted from the voltage level converting block 110. For another example, the voltage level of the input signal inputted to the voltage level converting block 110 may be higher than the voltage level of the output signal outputted from the voltage level converting block 110. In an embodiment of the present invention, the voltage level of the input signal is lower than the voltage level of the output signal. That is, the voltage level converting circuit 100 may be configured to output any one of an output signal having a high voltage level and an output signal having a ground voltage level in response to an input signal having a voltage level lower than the high voltage level of the output signal or a ground voltage level.

The boosting block 140 includes a first boosting block 120 and a second boosting block 130. The first boosting block 120 is connected between the voltage level converting block 110 and the input terminal IN for receiving an input signal. Although not illustrated, the first boosting block 120 may be connected to the input stage of the voltage level converting block 110. The second boosting block 130 is connected between the voltage level converting block 110 and an inverting input terminal INb for receiving an inverted input signal. Here, the inverted input signal means a signal obtained by inverting the input signal inputted to the input terminal IN. Although not illustrated, the second boosting block 130 may be connected to the inverting input stage of the voltage level converting block 110.

The first boosting block 120 is configured to apply a negative voltage to an input stage (not illustrated) of the voltage level converting block 110, instead of a ground voltage. For this operation, the first boosting block 120 is configured to boost a negative voltage. Similarly, the second boosting block 130 is configured to apply a negative voltage to an inverting input stage (not illustrated) of the voltage level converting block 110, instead of a ground voltage. For this operation, the second boosting block 130 is configured to boost a negative voltage.

The negative voltage boosting operation of the first boosting block 120 is performed according to the input signal inputted to the input terminal IN. For example, when a signal having a higher voltage level than the ground voltage (e.g., a logic high signal) is inputted to the input terminal IN, the first boosting block 120 may perform the negative voltage boosting operation. Similarly, the negative voltage boosting operation of the second boosting block 130 is performed according to the input signal inputted to the inverting input terminal INb. For example, when a signal having a higher voltage level than the ground voltage (e.g., a logic high signal) is inputted to the inverting input terminal INb, the second boosting block 130 may perform the negative voltage boosting operation.

According to an embodiment of the present invention, the negative voltage is applied to the input stage or inverting input stage of the voltage level converting block 110 by the first and second boosting blocks 120 and 130, instead of the ground voltage. When the negative voltage is applied to the input stage or the inverting input stage of the voltage level converting block 110, the operation speed of the input stage or inverting input stage may increase, and the input stage or inverting input stage may stably operate. For this reason, the operation speed of the voltage level converting block 110 may increase, and the output signal outputted to the output terminal OUT of the voltage level converting block 110 may be stabilized. The operations of the voltage level converting block 110, the first boosting block 120, and the second boosting block 130 will be described in detail with reference to the accompanying drawings.

FIG. 4 is a circuit diagram illustrating the voltage converting circuit according to an embodiment of the present invention. Referring to FIG. 4, the voltage level converting circuit 100 includes the voltage level converting block 110 for converting a voltage level, the first boosting block 120 for applying a negative voltage to the input stage (e.g., a first NMOS transistor N110) of the voltage level converting block 110, and the second boosting block 130 for applying a negative voltage to the inverting input stage (e.g., a second NMOS transistor N120) of the voltage level converting block 110.

The voltage level converting block 110 includes two PMOS transistors P110 and P120, two NMOS transistors N110 and N120, and two inverters IVT130 and IVT140. The inverters IVT130 and IVT140 are connected in series between the inverting input stage (e.g., the second NMOS transistor N120) of the voltage level converting block 110 and the output terminal OUT.

The first PMOS transistor P110 is connected between a high voltage input stage HV and the input stage (e.g., the first NMOS transistor N110) of the voltage level converting block 110. Furthermore, a gate of the first PMOS transistor is connected to the inverting input stage (e.g., the second NMOS transistor N120) of the voltage level converting block 110. The second PMOS transistor P120 is connected between the high voltage input stage HV and the inverting input stage (e.g., the second NMOS transistor N120) of the voltage level converting block 110. Furthermore, a gate of the second PMOS transistor P120 is connected to the input stage (e.g., the first NMOS transistor N110) of the voltage level converting block 110.

The first NMOS transistor N110 is connected between the first PMOS transistor P110 and the first boosting block 120. Furthermore, a gate of the first NMOS transistor N110 is connected to the input terminal IN. The second NMOS transistor N120 is connected between the second PMOS transistor P120 and the second boosting block 130. Furthermore, a gate of the second NMOS transistor N120 is connected to the inverting input terminal INb.

The first boosting block 120 includes a first diode D110, a first capacitor C110, and a third inverter IVT110. The first diode D110 is connected between the input stage (e.g., the first NMOS transistor N110) of the voltage level converting block 110 and a ground stage. The first capacitor C110 and the third inverter IVT110 are connected in series between the input stage (e.g., the first NMOS transistor N110) of the voltage level converting block 110 and the input terminal IN.

The second boosting block 130 includes a second diode D120, a second capacitor C120, and a fourth inverter IVT120. The second diode D120 is connected between the inverting input stage (e.g., the second NMOS transistor N120) of the voltage level converting block 110 and a ground stage. The second capacitor C120 and the fourth inverter IVT120 is connected in series between the inverting input stage (e.g., the second NMOS transistor N120) of the voltage level converting block 110 and the inverting input terminal INb.

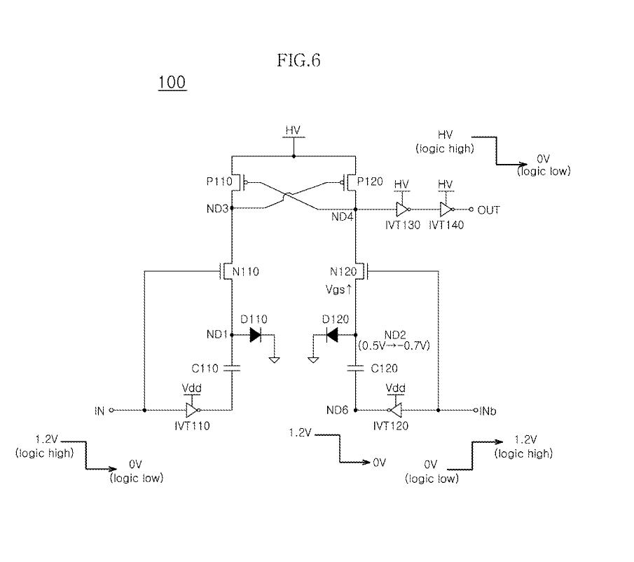

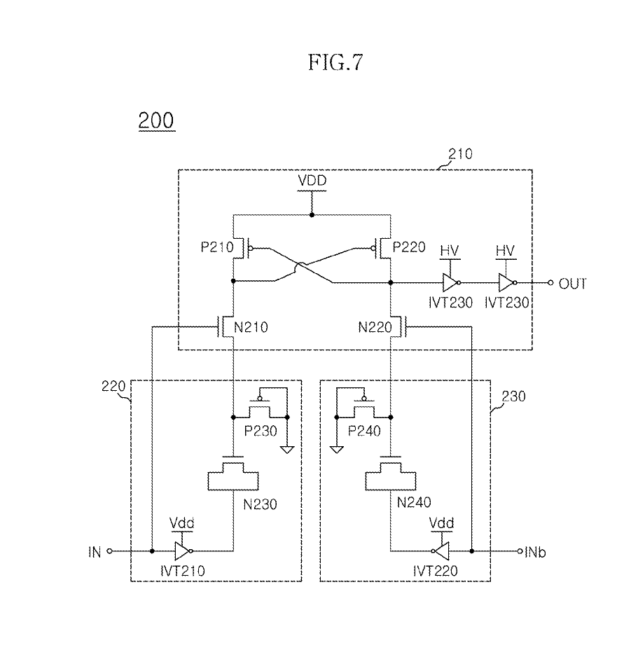

The operation of the voltage level converting circuit 100 according to an embodiment of the present invention will be described in detail with reference to FIGS. 5 and 6 illustrating signals inputted to the input terminal IN and the inverting input terminal INb.

FIG. 5 is a diagram explaining the operation of the voltage level converting circuit according to an embodiment of the present invention. In FIG. 5, suppose that an input signal inputted to the input terminal IN transits from a logic low signal (i.e., a signal having a ground voltage level) to a logic high signal (i.e., a signal having a low voltage level Vdd), for convenience of description. Furthermore, suppose that an input signal inputted to the inverting input terminal INb transits from a logic high signal (i.e., a signal having the low voltage level Vdd) to a logic low signal (i.e., a signal having the ground voltage level), for convenience of description. Here, suppose that the low voltage level Vdd is set to 1.2V and the threshold voltage of the first diode D110 is set to 0.5V.

Based on such suppositions, the operation of the voltage level converting circuit will be described as follows, with reference to FIGS. 4 and 5. First, when a logic high signal (i.e., 1.2V) is inputted to the input terminal IN, the input signal is inverted by the third inverter IVT110. That is, the voltage level of the fifth node ND5 is changed from 1.2V to 0V according to the voltage change of the input signal. Since the voltage level at one end of the first capacitor C110 connected to the fifth node ND5 was changed by a voltage difference of 1.2V, the voltage level at the other end of the first capacitor C110 connected to the first node ND1 may also be changed by a voltage difference of 1.2V, due to a coupling effect.

The voltage level of the first node ND1 may be set to a predetermined voltage level by the first diode D110 and the first capacitor C110. For example, if the threshold voltage of the first diode ND1 is set to 0.5V, the voltage level of the first node ND1 may be set to at least 0.5V. That is, the voltage level of the first node ND1 may be set to a voltage level when the first diode D110 is turned off.

When the initial voltage level of the first node ND1 is set to at least 0.5V by the first diode D110 and the logic high level (i.e., 1.2V) is inputted to the input terminal IN, the voltage level of the first node ND1 may be set to at most −0.7V by the coupling effect of the first capacitor C110. That is, a negative voltage may be applied to a source of the first NMOS transistor N110.

When the negative voltage is applied to the input stage of the voltage level converting block 110, that is, the source of the first NMOS transistor N110, a voltage difference Vgs between the gate and source of the first NMOS transistor N110 may increase more than when a ground voltage is applied to the source of the first NMOS transistor N110. When the voltage difference Vgs between the gate and source of the first NMOS transistor N110 increases, the first NMOS transistor N110 is sufficiently turned on. This means that the transition delay time at the first NMOS transistor N110, that is, the transition delay time at the input stage of the voltage level converting block 110 may be reduced. Also, the input stage of the voltage level converting block 110 may stably receive the input signal.

When the input stage (e.g., the first NMOS transistor N110) of the voltage level converting block 110 is sufficiently turned on by the logic high signal (e.g., 1.2V) inputted to the input terminal IN and the increased gate-source voltage difference Vgs, the second PMOS transistor P120 may also be sufficiently turned on without transition delay or with minimized transition delay. Therefore, the output signal outputted to the output terminal OUT stably transits from a logic low signal (e.g., a signal having the ground voltage level) to a logic high signal (e.g., a signal having the high voltage HV) without transition delay or with minimized transition delay.

According to an embodiment of the present invention, a negative voltage may be applied to the input stage (e.g., the first NMOS transistor N110) of the voltage level converting block 110 according to the voltage change of the input signal inputted to the input terminal IN. That is, instead of the ground voltage, the negative voltage may be applied to the input stage (e.g., the first NMOS transistor N110) of the voltage level converting block 110 by the first boosting block 120 including the first diode D110, the first capacitor C110, and the third inverter IVT110. Therefore, the output signal of which the voltage level is changed may be stably outputted to the output terminal OUT without transition delay or with minimized transition delay.

FIG. 6 is another diagram explaining the operation of the voltage level converting circuit according to an embodiment of the present invention. In FIG. 6, suppose that an input signal inputted to the input terminal IN transits from a logic high signal (i.e., a signal having a low voltage level Vdd) to a logic low signal (i.e., a signal having a ground voltage level), for convenience of description. Furthermore, suppose that an input signal inputted to the inverting input terminal INb transits from a logic low signal (i.e., a signal having the ground voltage level) to a logic high signal (i.e., a signal having the low voltage level Vdd), for convenience of description. Here, suppose that the low voltage level Vdd is set to 1.2V and the threshold voltage of the second diode D120 is set to 0.5V.

Under such suppositions, the operation of the voltage level converting circuit will be described as follows, with reference to FIGS. 4 and 6. First, when the logic high signal (i.e., 1.2V) is inputted to the inverting input terminal INb, the input signal is inverted through the fourth inverter IVT120. That is, the voltage level of the sixth node ND6 is changed from 1.2V to 0V according to the voltage change of the input signal. Since the voltage level at one end of the second capacitor C120 connected to the sixth node ND6 was changed by a voltage difference of 1.2V, the voltage level at the other end of the second capacitor C120 connected to the second node ND2 may also be changed by a voltage difference of 1.2V, due to a coupling effect.

The voltage level of the second node ND2 may be set to a predetermined voltage level by the second diode D120 and the second capacitor C120. For example, if the threshold voltage of the second diode D110 is 0.5V, the voltage level of the second node ND2 may be set to at least 0.5V. That is, the voltage level of the second node ND2 may be set to a voltage level when the second diode D120 is turned off.

When the initial voltage level of the second node ND2 is set to at least 0.5V by the second diode D120 and the logic high signal (i.e., 1.2V) is inputted to the inverting input terminal INb, the voltage level of the second node ND2 may be set to at most −0.7V by the coupling effect of the second capacitor C120. That is, a negative voltage may be applied to a source of the second NMOS transistor N120.

When the negative voltage is applied to the inverting input stage of the voltage level converting block 110, that is, the source of the second NMOS transistor N120, a voltage difference Vgs between the gate and source of the second NMOS transistor N120 may increase more than when the ground voltage is applied to the source of the second NMOS transistor N120. When the gate-source voltage difference Vgs of the second NMOS transistor N120 increases, the second NMOS transistor N120 is sufficiently turned on. This means that the transition delay time at the second NMOS transistor N120, that is, the transition delay time at the inverting input stage of the voltage level converting block 110 may be reduced, or the inverting input stage of the voltage level converting block 110 may stably receive the inverted input signal.

When the inverting input stage (e.g., the second NMOS transistor N120) of the voltage level converting block 110 is sufficiently turned on by the logic high signal (e.g., 1.2V) inputted to the inverting input terminal INb and the increased gate-source voltage difference Vgs, the first PMOS transistor P110 may also be sufficiently turned on without transition delay or with minimized transition delay. Furthermore, the second PMOS transistor P120 may be sufficiently turned off. Therefore, the output signal outputted to the output terminal OUT stably transits from a logic high signal (e.g., a signal having the high voltage level HV) to a logic low signal (e.g., a signal having the ground voltage level) without transition delay.

In an embodiment of the present invention, according to the voltage change of the input signal inputted to the inverting input terminal INb, a negative voltage may be applied to the inverting input stage (e.g., the second NMOS transistor N120) of the voltage level converting block 110. That is, instead of the ground voltage, the negative voltage may be applied to the inverting input stage (e.g., the second NMOS transistor N120) of the voltage level converting block 110 by the second boosting block 130 including the second diode D120, the second capacitor C120, and the fourth inverter IVT120. Therefore, the output signal of which the voltage level is changed may be stably outputted to the output terminal OUT without transition delay or with minimized transition delay.

FIG. 7 is a circuit diagram illustrating the voltage level converting circuit according to an embodiment of the present invention. Referring to FIG. 7, the voltage level converting circuit 200 includes a level converting block 210 for converting a voltage level, a first boosting block 220 for applying a negative voltage to an input stage (e.g., a first NMOS transistor N210) of the voltage level converting block 210, and a second boosting block 230 for applying a negative voltage to an inverting input stage (e.g., a second NMOS transistor N220) of the voltage level converting block 210.

The configuration and operation of the voltage level converting block 210 may be the same as the configuration and operation of the voltage level converting block 110, which have been described with reference to FIGS. 4 to 6. Therefore, the detailed descriptions thereof are omitted herein.

In an embodiment of the present invention, the first boosting block 220 may comprise a first diode P230, a first capacitor N230, and an inverter IVT210. Here, the first diode P230 may comprise a PMOS transistor and a first capacitor N230 may comprise an NMOS transistor. The configuration of the first capacitor N230 including an NMOS transistor has been taken as an example. However, the first capacitor N230 may include a different type of MOS transistor. The operation of the first boosting block 220 may be the same as the operation of the first boosting block 120 which have been described with reference to FIGS. 4 to 6. Therefore, the detailed descriptions thereof are omitted herein.

In an embodiment of the present invention, the second boosting block 230 may comprise a second diode P240, second capacitor N240, and an inverter IVT220. Here, the second diode P240 may comprise a PMOS transistor and a second capacitor N240 may comprise an NMOS transistor. The configuration of the second capacitor N240 including an NMOS transistor has been taken as an example. However, the second capacitor N240 may include a different type of MOS transistor. The operation of the second boosting block 230 may be the same as the operation of the second boosting block 130 which have been described with reference to FIGS. 4 to 6. Therefore, the detailed descriptions thereof are omitted herein.

According to an embodiment of the present invention, it is possible to improve the operation characteristic of the voltage level converting circuit.

While certain embodiments have been described above, it will be understood to those skilled in the art that the embodiments described are by way of example only. Accordingly, the voltage level converting circuit described herein should not be limited based on the described embodiments. Rather, the voltage level converting circuit described herein should only be limited in light of the claims that follow when taken in conjunction with the above description and accompanying drawings.

What is claimed is:

1. A voltage level converting circuit comprising:
a voltage level converting block configured to convert an input signal having a first voltage level into an output signal having a second voltage level; and
a boosting block connected to an input stage and an inverting input stage of the voltage level converting block, and configured to provide a negative voltage to the input stage or the inverting input stage.

2. The voltage level converting circuit according to claim 1, wherein the input stage comprises a first NMOS transistor, and the inverting input stage comprises a second NMOS transistor.

3. The voltage level converting circuit according to claim 2, wherein the boosting block comprises a first boosting block configured to generate a negative voltage in response to the input signal and provide the generated negative voltage to a source of the first NMOS transistor.

4. The voltage level converting circuit according to claim 3, wherein the first boosting block comprises:
a first inverter connected to an input terminal for receiving the input signal;
a first capacitor connected between an output stage of the first inverter and the source of the first NMOS transistor; and
a first diode connected between the source of the first NMOS transistor and a ground stage.

5. The voltage level converting circuit according to claim 4, wherein the first diode is configured to set the source of the first NMOS transistor at a voltage level equal to or larger than a threshold voltage of the first diode, and
the first capacitor is configured to boost the voltage level of the source of the first NMOS transistor to a negative voltage according to voltage change of the input signal.

6. The voltage level converting circuit according to claim 4, wherein the first diode comprises a PMOS transistor.

7. The voltage level converting circuit according to claim 4, wherein the first capacitor comprises a MOS-type transistor.

8. The voltage level converting circuit according to claim 3, wherein the boosting block further comprises a second boosting block configured to generate a negative voltage in response to an inverted input signal obtained by inverting the input signal, and provide the generated negative voltage to a source of the second NMOS transistor.

9. The voltage level converting circuit according to claim 8, wherein the second boosting block comprises:
a second inverter connected to an inverting input terminal for receiving the inverted input signal;
a second capacitor connected between an output stage of the second inverter and the source of the second NMOS transistor; and
a second diode connected between the source of the second NMOS transistor and a ground stage.

10. The voltage level converting circuit according to claim 9, wherein the second diode is configured to set the source of the second NMOS transistor at a voltage level equal to or larger than a threshold voltage of the second diode, and
the second capacitor is configured to boosting the voltage level of the source of the second NMOS transistor to a negative voltage according to voltage change of the inverted input signal.

11. The voltage level converting circuit according to claim 9, wherein the second diode comprises a PMOS transistor.

12. The voltage level converting circuit according to claim 9, wherein the second capacitor comprises a MOS-type transistor.

13. The voltage level converting circuit according to claim 8, wherein any one of the first and second boosting blocks is operated according to a logic state of the input signal.

14. A voltage level converting circuit comprising:
a voltage level converting block configured to convert an input signal having a first voltage level into an output signal having a second voltage level; and
a boosting block configured to provide a negative voltage to a first node of the voltage level converting block in response to the input signal, or provide a negative voltage to a second node of the voltage level converting block in response to an inverted input signal obtained by inverting the input signal.

15. The voltage level converting circuit according to claim 14, wherein the first node is connected to a source of a first NMOS transistor forming an input stage of the voltage level converting block, which receives the input signal, and
the second node is connected to a source of a second NMOS transistor forming an inverting input stage of the voltage level converting block, which receives the inverted input signal.

16. The voltage level converting circuit according to claim 15, wherein the boosting block comprises:
a first boosting block configured to generate a negative voltage in response to the input signal and provide the generated negative voltage to the first node; and
a second boosting block configured to generate a negative voltage in response to the inverted input signal and provide the generated negative voltage to the second node.

17. The voltage level converting circuit according to claim 16, wherein the first boosting block comprises:
a first inverter connected to an input terminal for receiving the input signal;
a first capacitor connected between an output stage of the first inverter and the first node; and
a first diode connected between the first node and a ground stage.

18. The voltage level converting circuit according to claim 17, wherein the first diode is configured to set the first node at a voltage level equal to or larger than a threshold voltage of the first diode, and
the first capacitor is configured to boost the voltage level of the first node to a negative voltage according to voltage change of the input signal.

19. The voltage level converting circuit according to claim 16, wherein the second boosting block comprises:
a second inverter connected to an inverting input terminal for receiving the inverted input signal;
a second capacitor connected between an output stage of the second inverter and the second node; and
a second diode connected between the second node and a ground stage.

20. The voltage level converting circuit according to claim 19, wherein the second diode is configured to set the second node at a voltage level equal to or larger than a threshold voltage of the second diode, and
the second capacitor is configured to boost the voltage level of the second node to a negative voltage according to voltage change of the inverted input signal.

21. The voltage level converting circuit according to claim 16, wherein any one of the first and second boosting blocks is operated according to a logic state of the input signal.
